(19) United States
(12) Patent Application Publication
(10) Pub. No.: US 2026/0072364 A1
(43) Pub. Date: Mar. 12, 2026

(54) METHOD FOR PRODUCING AN OPTICAL IMAGING SYSTEM FOR A MICROLITHOGRAPHY APPARATUS

(71) Applicant: Carl Zeiss SMT GmbH, Oberkochen (DE)

(72) Inventors: Thomas Fischer, Aalen (DE); Steffen Fritzsche, Aalen (DE); Daniel Golde, Oberkochen (DE); Toralf Gruner, Aalen (DE); Tobias Mueller, Langenau (DE); Daniel Pagel, Essingen (DE); Hendrik Wagner, Aalen (DE)

(21) Appl. No.: 19/393,243

(22) Filed: Nov. 18, 2025

Related U.S. Application Data
(63) Continuation of application No. PCT/EP2024/063932, filed on May 21, 2024.

(30) Foreign Application Priority Data
May 25, 2023 (DE) 10 2023 113 819.7

(51) Int. Cl. G03F 7/00; G01N 21/956; G02B 13/14; G02B 17/00; G03F 1/22

(52) U.S. Cl. CPC G03F 7/70975; G01N 21/956; G02B 13/143; G02B 17/008; G03F 1/22; G03F 7/70233; G03F 7/70258; G03F 7/70508; G03F 7/706; G03F 7/7085; G01N 2021/95676

(57) ABSTRACT

A method for producing an optical imaging system for an EUV microlithography apparatus, and a related optical system and apparatus.

### CROSS-REFERENCE TO RELATED APPLICATIONS

The present application is a continuation of, and claims benefit under 35 USC 120 to, international application No. PCT/EP2024/063932, filed May 21, 2024, which claims benefit under 35 USC 119 of German Application No. 10 2023 113 819.7, filed May 25, 2023. The entire disclosure of each of these applications is incorporated by reference herein.

### FIELD

The disclosure relates to a method for producing an optical imaging system for an EUV microlithography apparatus and to an optical imaging system for an EUV microlithography apparatus. A field of application is the production or restoration of optical imaging systems designed as projection lenses of EUV projection exposure apparatuses or EUV mask inspection apparatuses for the inspection of masks (reticles) for EUV microlithography.

### BACKGROUND

Nowadays, microlithographic projection exposure methods are mainly used for the production of semiconductor devices and other finely structured components, such as photolithographic masks. Here, masks (reticles) or other pattern-producing devices are used that bear or form the pattern of a structure to be imaged, for example a line pattern of a layer of a semiconductor device. The pattern is positioned in a projection exposure apparatus between an illumination system and an optical imaging system, usually referred to as a projection lens or projection optical unit, in the region of the object plane of the imaging system and illuminated with illumination radiation shaped by the illumination system. The radiation changed by the pattern travels along an imaging beam path through the imaging system, which images the pattern onto the substrate to be exposed on a reduced scale. The surface of the substrate is arranged in the image plane of the imaging system, which is optically conjugate to the object plane. The substrate is usually coated with a radiation-sensitive layer (resist, photoresist).

One of the objectives in the development of projection exposure apparatuses is to lithographically produce structures with increasingly smaller dimensions on the substrate, e.g. in order to achieve higher integration densities in semiconductor devices. One approach is to work with shorter wavelengths of electromagnetic radiation. For this purpose, optical systems, among other things, have been developed that use electromagnetic radiation from the extreme ultraviolet range (EUV) with operating wavelengths in the range between 5 nanometres (nm) and 30 nm, such as at 13.5 nm. Typically, imaging systems for EUV microlithography apparatuses use only mirrors to image structures from the object plane into the image plane, e.g. from a reticle onto a wafer.

Many modern EUV projection lenses are modular in design. Optical modules are installed at assigned installation positions in a common force frame and comprise a mirror each and are located in the finished mounted state in each case at installation positions provided for the optical modules and then form the imaging beam path with the optically effective surfaces of the mirrors. To facilitate the assembly, maintenance and, if appropriate, optimization of such imaging systems, (one or more) optical modules can be designed as exchangeable optical modules, i.e. as replacement modules (see e.g. DE 10 2021 201 162 A1).

EUV microlithography apparatuses are technically highly complex capital goods, the procurement and operation of which entails significant costs to their end users. In general, such investments are profitable if the microlithography apparatus at its site of use can reliably and permanently meet the technical specifications and be operated productively without major interruptions.

### SUMMARY

The disclosure seeks to provide a method for producing an optical imaging system for an EUV microlithography apparatus and a corresponding optical imaging system and an EUV microlithography apparatus equipped therewith in such a way that an optical imaging system reliably meets the specifications expected by the manufacturer at its point of use and can be operated highly productively with at most minimal downtime for maintenance purposes.

A method according to the disclosure can be used to produce (or restore) an optical imaging system for an EUV microlithography apparatus. The optical imaging system typically comprises a plurality of optical modules each carrying a mirror along an imaging beam path leading from an object plane to an image plane of the imaging system, the optical modules being installed at assigned installation positions with a fixed spatial relationship to a force frame. Generally, at least one of the optical modules is designed as an exchangeable replacement module with a mirror selected as the correction mirror.

For the purposes of this application, an “optical module” comprises a mirror and further components. The mirror can comprise a mirror substrate. A region of the substrate surface is machined with optical precision and thus substantially determines the surface shape of the mirror. In the case of an optical module completed for the productive operation of the EUV apparatus, this region of the substrate surface can be coated with a reflection coating that has a reflective effect on EUV radiation in order to optimize reflectivity. Substrate-fixed components can also be attached to the mirror substrate, e.g. substrate-side components of a holding frame or a bearing device for supporting the mirror substrate on or in a holding frame and, if appropriate, components of actuators and/or of sensors. If appropriate, the position of the mirror substrate in relation to the holding frame is settable or changeable via suitable setting devices, e.g. for the purpose of rigid body alignment. Components of the setting device may be attached to the mirror substrate. The holding frame may have attachment structures, e.g. flange-like attachment structures, for attaching the holding frame to the force frame. The optical module may be designed such that the interface lies between the exchangeable optical module and the force frame, between the holding frame and the force frame or within the holding frame, and so the optical module comprises the mirror substrate and the components of the holding frame that are coupled thereto. It is also possible that the interface is located in the region of the holding frame or in the region of a bearing device, so that the optical module comprises only the mirror substrate and the attached components of the holding frame or of the bearing device and, if appropriate, components of sensors and/or actuators mounted fixedly to the substrate, and components of the holding frame or a bearing device and/or of sensors and/or actuators, which components are mounted fixedly to the force frame, are not exchanged during a replacement operation.

The method involves a concept in which at least one of the optical modules is designed as an exchangeable replacement module with a mirror selected as the correction mirror. Such an optical module is referred to here for short as “optical module with correction mirror” or as “replacement module with correction mirror”. An idea behind this is that it is still possible with the aid of a correction mirror to correct any residual aberrations that remain after alignment of the system by changing the optically effective surface of the correction mirror, based on results of system measurements, in such a way that the change can reduce the level of residual aberrations to such an extent that the imaging system meets its specification. A correction mirror is a mirror that is provided or selected as a correction mirror or whose surface shape is to be changed, if appropriate, in order to correct residual aberrations remaining after the rigid body alignment. The method generally comprises a plurality of steps, which are typically marked with uppercase letters here to simplify the reference.

According to a step A, a shape measurement is performed on the mirror selected as correction mirror in order to determine its surface shape in the optically used region. The shape measurement is performed, for example interferometrically, with the aid of a component measurement system. For example, a Fizeau interferometer can be used as the component measurement system. WO 2006/077145 A2 discloses examples of such interferometers. From the shape measurement, the surface shape of the correction mirror may be known within the scope of the measurement accuracy of the component measurement system.

The substrate surface can be machined so smoothly in the optically used region that it strongly reflects light from the visible part of the spectrum (VIS), for example. For shape measurements, for example using measurement light from the VIS range, it is therefore not necessary that the substrate surface in the optically used region already has a coating that has a reflective effect on EUV radiation. The shape measurement can be performed on the uncoated substrate or on the coated substrate.

In addition, a tool module with a tool mirror can be provided according to a step B of the method. A “tool module” within the meaning of this application is an optical module which is assigned to a specific optical module or a replacement module with correction mirror, has mounting structures compatible with respect to the installation position of the assigned optical module and comprises a tool mirror which, according to a shape measurement with a component measurement system, has the same or substantially the same surface shape as the correction mirror of the assigned replacement module with correction mirror.

A tool mirror can have, within manufacturing tolerances, the same surface shape and the same optical effect as the assigned correction mirror. However, this is not mandatory. A tool mirror may have an optical effect that is measurably different from the optical effect of the assigned optical module with correction mirror. However, any possible difference in optical effect should be so small that the aberration level does not become too bad, so that a meaningful system measurement remains possible.

Typically, mirrors for EUV systems each comprise a mirror substrate, which can be made of, e.g., consist of, for example, a glass or a glass ceramic with a low coefficient of thermal expansion and has a substrate surface which has been machined with optical precision and substantially determines the surface shape of the mirror. To optimize the reflectivity for the incident EUV radiation, this substrate surface can have a reflection coating that has a reflective effect on EUV radiation, e.g. a multiple reflection layer (multilayer) built up from many individual layers. A tool mirror can also be constructed in this manner, so that the reflection properties, such as the reflectance and the effect on the wavefront, are as similar as possible to those of the assigned correction mirror.

Tool mirrors can have relaxed specifications, for example with regard to mechanical handling, as well as small mechanical defects (for example small scratches, protrusions, cosmetic impairments) or life-cycle effects. It is desirable to have as precise a knowledge as possible of the surface shape of the tool mirror at the time of the system measurement.

It is possible, for example, to use, as a tool module, an optical module which is nominally identical to the assigned optical module to be exchanged, but has degraded after prolonged use at a different location to such an extent that it had to be replaced. Thus, even used optical modules can still be used as “means to an end”, to be precise as an aid in system measurement. This can help save resources and limits costs.

It is also possible to install specially tolerated mirrors as tool mirrors in order to save time for the new production of a new tool mirror. In this sense, tool mirrors might serve only as auxiliary mirrors in an optical imaging system that is be newly aligned in order to enable reliable system measurement.

According to a step C, an auxiliary imaging system is set up by installing optical modules with mirrors at the associated installation positions of the force frame, wherein the assigned tool module is installed at the installation position of the optical module designed as a replacement module (replacement module with the correction mirror). The auxiliary imaging system can be a provisional imaging system in so far as it differs structurally from the optical imaging system to be produced or to be restored, inter alia in that the assigned tool module is installed instead of an optical module equipped with correction mirror.

According to a step D, a system measurement is then carried out on the assembled auxiliary imaging system for determining an imaging quality of the auxiliary imaging system. This system measurement can be carried out after the optical modules have been installed and the optical modules in their installation positions have undergone a rigid-body alignment. The rigid-body alignment of the optical modules can be supported by results of system measurements to ensure that the possibilities of rigid-body alignment are exploited as well as possible and that the imaging performance of the auxiliary imaging system is optimized already in the direction of the desired target imaging performance. A system measurement system, for example a wavefront measurement system, can be used to carry out the system measurement.

In a step E, the imaging quality measured in step D is compared with a target imaging quality of the optical imaging system, which results, for example, from the specification. The measured imaging quality is typically compared with the target imaging quality to determine an imaging quality error. On the basis of the comparison, it can then be determined in step F in which way a change in the surface shape of the (at least one) correction mirror can be generated in order to reduce the imaging quality error and thus to bring the auxiliary imaging system into specification.

The information obtained in step F can be used in step G. In this method step G, the mirror selected as the correction mirror is machined in such a way that a change in the surface shape is generated in the direction of a modified surface shape suitable for reducing the imaging quality error.

For this purpose, an uncoated mirror (mirror substrate that has been polished to a high gloss in the optically used region or has been finely machined to a high gloss in another way, but has not yet been coated) can be used as the correction mirror, the surface shape of which in the optically used region can be machined via a suitable shape machining process, e.g. by ion beam etching, and thereby changed. A reflection coating designed for EUV radiation can then be applied. It is also possible to use a correction mirror whose mirror substrate already has an EUV reflection coating. The surface shape of a correction mirror already provided with a reflection coating can be machined, for example, in a way as described in documents US 2012/212721 A1, US 2014/307308 A1, US 2012/300184 A1, DE 10 2014 225 197 A1, US 2019/018324 A1, DE10 2021 213 148 A1, DE 10 2015 201 141 A1, US 2016/209750 A1 or DE 10 2011 076014 A1.

After finishing the surface-shape-changing machining of the mirror selected as the correction mirror, an exchange operation (swap operation) takes place in accordance with step H. In the process, the installed tool module is removed from its installation position and the assigned optical module with the correction mirror having the modified surface shape, which optical module is designed as a replacement module, is installed in the installation position instead of the tool module. Thus, the auxiliary imaging system becomes with regard to the structural components the desired imaging system, which is also referred to as the final imaging system.

The success of the measure is verified in accordance with step I by performing a system measurement to determine the imaging quality of the optical imaging system for control purposes.

As a rule, after installation of the optical module provided with a correction mirror, a rigid-body alignment of optical modules installed in the imaging system is desirable in order to optimize the imaging quality of the imaging system. Here, a plurality of further system measurements and, based thereon, alignment steps for optimizing the spatial positions of the optical modules in their respective installation positions can be useful in an iterative method. Thus, the method can comprise an evaluation of results of the system measurement and, if the result of the system measurement indicates an imaging quality that lies outside the tolerances, an alignment operation for aligning installed optical modules in their rigid-body degrees of freedom for improving the imaging quality, and a further system measurement, wherein alignment operations and system measurements are repeated until a system measurement indicates an imaging quality that lies within the tolerances.

In a method, an assigned tool module with a tool mirror is thus used for at least one optical module which is designed as an exchangeable replacement module with a correction mirror. The tool module is installed temporarily in the force frame of the optical imaging system. Further work can already be carried out on the resulting auxiliary imaging system to prepare for commissioning, while at the same time the mirror provided as a correction mirror can be machined on the basis of system measurements on the auxiliary imaging system equipped with the tool mirror. This can help result in significantly improved time management, as many activities used in the course of production can be carried out at the same time and, if appropriate, in different locations.

After a system measurement on the auxiliary imaging system has determined how the mirror selected as the correction mirror is machined in order to reduce the level of residual aberrations, the machining of the mirror selected as the correction mirror (step G) can already be started and carried out while the auxiliary imaging system is still in operation and can still be used, for example, for activities in connection with the preparation of commissioning. This can help shorten the time used for commissioning the imaging system to be produced. This can help minimize unusable times for the EUV microlithography apparatus (downtime). Even if the machining recipe for changing the surface shape of the correction mirror is already available, the tool mirror can remain in the auxiliary imaging system for a certain period of time until the optical module with the machined correction mirror, which is designed as a replacement module, arrives and can be installed. This time can be used, for example, for tests or can already be used for desired commissioning work that does not require full optical performance. Thus, the auxiliary imaging system with the installed tool module can be operated in an auxiliary mode to perform tests and/or to prepare for commissioning at the second location.

Although it is possible that there is only a single exchangeable optical module with a mirror selected as the correction mirror in the optical imaging system, it possible that a plurality of such optical modules are provided, for example, two, three or four such replacement modules and correspondingly assigned tool mirrors.

Shape measurement(s) and system measurement(s) can be performed at the same location, e.g. at the location of the manufacturer of the mirrors and/or imaging system in the same measurement space or in different measurement spaces of the same production site.

However, according to a development, provision is made for the shape measurement(s) to be carried out at a first location and the system measurement to be carried out at a second location away from the first location. For example, the first and second locations can be located in different cities or different regions of a country or in different countries and/or on different continents. For example, a distance between the first and the second location can be more than 100 km and/or more than 1000 km and/or more than 10,000 km.

This spatial separation between component measurement (measurements on the individual components) and system measurement (measurements on the assembled system comprising a plurality of components) can offer numerous technical and economic advantages and can take into account that there are numerous sources of error that are difficult to control in the production of such a highly complex optical imaging system.

The shape measurement can be carried out at the location of the manufacturer of the mirror and/or of the imaging system (first location), i.e. spatially close to the manufacturing of the mirrors. This can help allow for efficient, low-error interaction between manufacturing and control via shape measurement. There is no need to keep expensive system measurement technology at the first location.

The second location can be, for example, the location of a systems integrator using the optical imaging system to set up the EUV microlithography apparatus consisting of many further components. If appropriate, a system measurement can also be carried out at the location of use by the end customer, so that the second location may even be the location of use. The system measurement can be used to determine the imaging quality of the set-up auxiliary imaging system. This measurement then also can record influences of the environment of the use and any influences that may arise during transport between the production location of the mirrors and the location of use of the entire system.

It is also possible that a system measurement is carried out at a systems integrator's site and the exchange (swap operation) takes place at the end customer's site. This can help allow for parallelization of the correction mirror manufacturing and the transport of the entire system to the customer, which also makes it possible to save time. The individual method steps can thus also be spread over more than two, for example three, different locations.

This approach can take into account the fact that both the individual components of the imaging system and the entire system that is made up of many individual components desirably meets their respective specifications. It can also take into account that a system measurement at the site of the manufacturer of the components does not necessarily have sufficient significance, since it is highly probable that different environmental conditions exist at the location of subsequent use than at the first location. This variant therefore can assume a spatial separation between the first location and the second location and optimizes the distribution of the desired measurement tasks.

A wavefront measurement system can be used to carry out the system measurement. A spatially resolving wavefront measurement for a plurality of field points can be provided. The system measurement can be carried out directly in the EUV microlithography apparatus using integrated measurement technology. This can help eliminate setting up a separate system measurement facility. Instead, integrated measurement technology, which can also be used in the further operation of the EUV microlithography apparatus, can be used.

The optical effect of a mirror is determined, among other things, by the surface shape, which is also referred to here as the “surface figure”. Deviations from the target surface shape specified in accordance with the optical design are accordingly referred to as surface figure errors. It is desirable for each mirror to have a precisely specified surface shape. Mirror surfaces for EUV systems are often designed as free-form surfaces, meaning that they have a surface shape that differs significantly from a spherical or rotationally symmetrically aspherical surface shape. Precise manufacturing is extremely complex. This can make an exact shape measurement using a component measurement system all the more desirable.

Measurement errors may occur in these shape measurements. In addition, machining errors can occur during shaping. Furthermore, the surface shape can be changed via measures taken during assembly, for example by introducing deformations due to adhesive effects or screw-connection effects, which can also be referred to as surface-figure deformation errors (SFD errors). In addition, thermal effects, which influence the surface shapes, can occur in the fully assembled system. Position errors can also occur, e.g. if the installation position in the finished system differs from the installation position during component measurement.

This embodiment also takes into account that before a finished optical imaging system is delivered to a systems integrator or a customer or end-user, it is generally not known in what type of environment such EUV microlithography apparatuses are to be operated at the end-user's site. For example, the usable performance can be influenced by the gravity condition at the installation site, possible deformations of the ground caused by other machines in the vicinity, etc., to such an extent that the properties desired for productive operation cannot be achieved. A system measurement at the end user's location can capture these circumstances.

In the scenario outlined here, installing the tool mirror can create a fundamentally functional imaging system, the imaging performance of which may not meet the specification for productive operation, but is sufficient, for example, to carry out further tests on the imaging system and/or to prepare the imaging system for commissioning at the second location. By operating the imaging system with the installed tool module in an auxiliary mode for carrying out tests and/or preparing for commissioning at the second location, the downtime of the EUV microlithography apparatus at the second location can be kept short and useful measures are also possible during the time that is used to complete work on the selected mirror for changing or correcting the surface shape. For example, it may be the case that the auxiliary mode of the auxiliary imaging system and the machining of the correction mirror for changing the surface shape are carried out simultaneously or with a time overlap or in parallel at least in phases.

When this work is completed and the selected optical module with the corrected surface shape has arrived at the second location, the tool module can be removed and the optical module with the selected mirror having the modified surface shape can be reinstalled in the same installation position.

The tool module may then free for further use and can be used in the same way, for example, when constructing another, nominally identical optical imaging system.

According to a development, the shape measurement for determining the surface shape of the tool mirror was carried out with the same component measurement system with which the selected mirror (correction mirror), which was replaced by the tool mirror, was or is also measured. This procedure can take into account the fact that even component measurement systems cannot always measure without errors, and as a result their measurement results can include an absolute error that cannot be determined or can be determined only with great effort. However, if the correction mirror and the assigned tool mirror are measured with the same component measurement system, the results of the shape measurement in both cases include the same absolute error, as a consequence of which the error disappears or plays no role in the further course of the method. In other words, if the only issue of interest is the optical difference effect due to the change in the surface shape, the absolute errors of the component measurement for both mirrors of the exchange pair cancel each other out in the optical difference formation.

In general, it does not have to be the very same measurement system, but it can be sufficient if the measurement system is identical, e.g. a twin of the same design. It is desirable to ensure that the absolute error between two surface figure measurement systems is the same. For this reason, it is desirable to use the very same measurement system.

In the case of a method according to the disclosure, it is not absolutely necessary that all mirrors used for the construction of the optical imaging system undergo a shape measurement to determine the surface shape. According to a development, however, provision is made for a shape measurement for determining a surface shape to be carried out on each of the mirrors provided for the construction of the imaging system via a component measurement system. If the surface shapes are known within the scope of measurement accuracy, more reliable conclusions and predictions can be derived from the results of the system measurement.

According to this concept, a tool mirror may be used only temporarily to thus temporarily set up an auxiliary imaging system, which can already be used for test purposes or the like while a replacement module with correction mirror that is to be installed permanently is machined for finally defining its surface shape and is then delivered. After the exchange operation, the tool mirror is then free to be used, if appropriate, in the construction of another optical imaging system, which involves a mirror with the existing or a modified surface shape, either as a tool mirror for temporary use or as a “sharp” mirror for final placement in the imaging system for later use. According to a development, the same tool module can therefore be used multiple times. A tool mirror originally installed in an imaging system can thus be re-installed later in another imaging system that will be newly constructed, for example for first-wavefront measurement as a tool mirror or for alignment as a replacement mirror with a corrected surface figure. This concept is here also referred to as the “concept of circulating tool mirrors”. Depending on the desire, parts of a tool module with tool mirrors can be remanufactured, repaired or interchanged. The number of circulation cycles for a tool mirror can be limited, for example to two, three, four or five or more uses.

This concept can also be desirable in terms of knowledge about the measurement systems. According to a development, at least one further component measurement is carried out on a tool mirror in addition to a first component measurement, on the tool mirror with the same component measurement system, and the results of two or more shape measurements on the same tool mirror performed with the same component measurement system with a temporal distance are compared in order to be able to identify possible drift effects at the component measurement system. In this variant, a specific tool mirror thus serves as a reference element for the calibration of the component measurement system.

Multiple use of the same tool mirrors in different imaging systems can also be utilized in such a way that system measurements for determining the imaging quality of the imaging system with installed tool mirror (one or more) are carried out on the respective imaging systems, as well as reconstruction calculations on the measurement results of the system measurements for determining a shape error contribution of the tool mirror. In other words, by mathematically combining measurement results of system measurements on the imaging systems, a surface figure error introduced by the surface shape of the tool mirror can be determined by reconstruction.

The use of such tool modules with tool mirrors can also offer further features for manufacturing processes for optical imaging systems for EUV microlithography apparatuses. For example, according to a development, at least one further component measurement can be carried out on the tool mirror with the aid of the component measurement system, and the results of two or more shape measurements carried out on the same tool mirror with the same component measurement system with a temporal distance can be used to determine drift effects at the component measurement system.

According to a development, multiple use of the same tool module in different imaging systems is provided.

Furthermore, system measurements are carried out on the imaging systems to determine the imaging quality of the imaging systems in each case when the tool module is installed.

An originally installed tool mirror can later be installed again in a newly delivered system for first-wavefront measurement (system measurement) and alignment. Depending on the desire, parts of the tool modules can be remanufactured, repaired or interchanged here. The multiple use of tool modules with tool mirrors is also referred to here as the “concept of circulating tool mirrors”.

The disclosure also relates to an optical imaging system for an EUV microlithography apparatus, which is produced (initial production) or restored (after a phase of use) by the method, and to an EUV microlithography apparatus equipped therewith.

### BRIEF DESCRIPTION OF THE DRAWINGS

Further features and aspects of the disclosure will become apparent from the claims and from the description of exemplary embodiments of the disclosure, which are explained below on the basis of the figures, in which:

FIG. 1 shows components of an EUV microlithography projection exposure apparatus with a projection lens; and

FIGS. 2A to 2D show different steps of a method for producing an optical imaging system.

### DETAILED DESCRIPTION

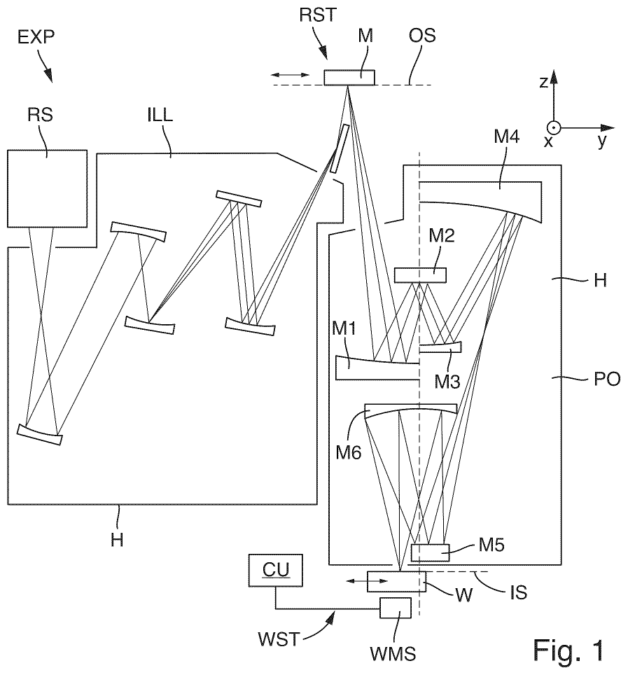

Exemplary embodiments of the disclosure will be described below referencing the production and commissioning of a projection exposure apparatus for EUV lithography. The schematic FIG. 1 shows components of an EUV microlithography projection exposure apparatus EXP for exposing a radiation-sensitive substrate W, arranged in the region of an image plane IS of a projection lens PO, with at least one image of a pattern of a reflective mask M arranged in the region of an object plane OS of the projection lens. The projection lens PO is an example of an optical imaging system for EUV lithography. The projection lens PO images the pattern of the mask on a reduced scale into the image plane in which the substrate W to be exposed, e.g. a semiconductor wafer, is arranged.

The projection exposure apparatus operates with radiation from a primary radiation source RS. An illumination system ILL is used to receive the radiation from the primary radiation source and to shape illumination radiation directed onto the pattern of the mask M. The projection lens PO is used to image the structure of the pattern onto the light-sensitive substrate W.

The primary radiation source generates radiation in the extreme ultraviolet (EUV) range, such as at wavelengths between 5 nm and 15 nm. In order for the illumination system and the projection lens to operate in this wavelength range, they are constructed with optical elements that are reflective for EUV radiation.

The illumination system shapes the radiation coming from the radiation source and with it illuminates an illumination field that is located in or near the object plane OS of the projection lens PO. The shape and size of the illumination field determine the shape and size of the effectively used object field in the object plane OS. The illumination field is generally slit-shaped with a large aspect ratio between width and height.

A device RST for holding and manipulating the mask M (reticle) is arranged such that the pattern arranged on the mask lies in the object plane OS of the projection lens PO, which is also referred to here as the reticle plane. In this plane, the mask can be moved for scanner operation in a scan direction (y-direction) perpendicular to the reference axis of the projection lens (parallel to the z-direction) with the aid of a scan drive.

The substrate W is held by a device WST comprising a scanner drive to move the substrate synchronously with the mask M in a scanning direction (y-direction) perpendicular to the reference axis. Depending on the design of the projection lens PO, these movements of the mask and substrate can be parallel or counter-parallel to each other.

The device WST, which is also referred to as “wafer stage”, and the device RST, which is also referred to as “reticle stage”, are part of a scanner device which is controlled by a scan control device, which in the embodiment is integrated into the central control device CU of the projection exposure apparatus.

The projection lens PO of the example comprises six mirrors M1 to M6 with concave or convex mirror surfaces. These can be free-form surfaces. An intermediate image is generated between the object field and the image field. Other constructions, e.g. with more or fewer mirrors with or without intermediate image, are possible.

All optical components of the projection exposure system EXP are housed in evacuable housings H. The projection exposure apparatus is operated under vacuum. EUV projection exposure apparatuses are known, for example, from the laid-open specification DE 10 2021 201 162 A1, the disclosure of which is incorporated by reference into the content of this description.

The projection exposure apparatus comprises a wavefront measurement system WMS, which operates at the EUV operating wavelength and which is designed to measure the wavefront of the projection radiation, which travels in the projection lens from the mask to the substrate to be exposed. A spatially resolving measurement for a plurality of field points can be provided. For example, wavefront measurement systems of the type described in U.S. Pat. Nos. 7,333,216 B2 or 6,650,399 B2 may be provided, the disclosure of which is incorporated by reference into the content of this description.

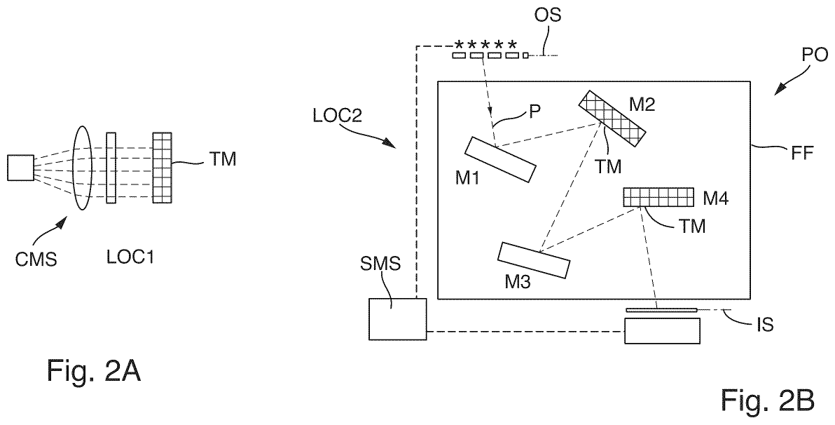

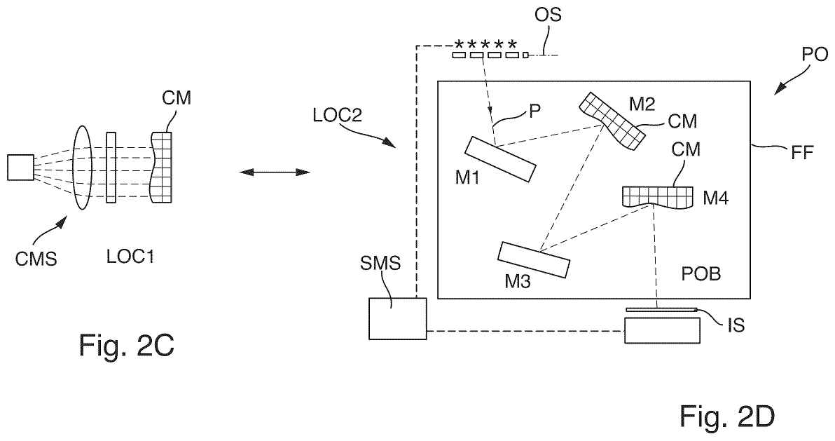

With reference to the schematic FIGS. 2A to 2D, some features of methods presented here for the production of optical imaging systems in the form of EUV projection lenses are explained. FIGS. 2A to 2D illustrate different method steps, some of which take place at different locations. FIGS. 2A and 2C represent processes that take place at the location of the manufacturer of the projection lens (first location, LOC1). FIGS. 2B and 2D refer to processes and, respectively, method steps that take place at a remote, second location LOC2 at the site of the end user of the projection lens in its production hall.

In the schematic example, the projection lens has four mirrors (first mirror M1, second mirror M2, third mirror M3 and fourth mirror M4), which are mounted in appropriate installation positions of a force frame FF. In the ready-to-use assembled and aligned and corrected state (FIG. 2D), the projection lens PO meets its specification intended for productive operation and can be used for the production of finely structured components such as semiconductor chips. The projection radiation used for the imaging travels along a projection beam path P schematically shown in FIGS. 2B and 2D from the pattern of the reticle M via the reflective surfaces of the first mirror M1, the second mirror M2, the third mirror M3 and the fourth mirror M4 to the surface of the semiconductor wafer W to be structured, on which an image of the mask is generated.

At the location of final assembly and use (second location, LOC2), a system measurement system SMS is available, with which the wavefront of the projection radiation travelling from the object plane OS to the image plane IS can be measured by way of a spatially resolving wavefront measurement and compared with the wavefront used in accordance with the specification. This allows the actual imaging quality to be compared with the target imaging quality according to the specification.

The system measurement system SMS is used as part of the assembly and alignment of the projection lens in order to bring the projection lens into the ready-to-use state, i.e. into specification. In the example, the system measurement system SMS is a part of the projection exposure apparatus and is also used during operation of the projection exposure apparatus for wavefront measurements in order to be able to adapt the imaging properties of the projection lens to changed boundary conditions, if appropriate with the aid of manipulators.

The wavefront of the projection radiation P is influenced, among other things, by the surface shape of the optically used regions of the mirror surfaces. This surface shape is also referred to here as a “surface figure”. Furthermore, the quality of the wavefront is strongly determined by the accuracy of the spatial position of the reflective surfaces within the projection lens. Any deviation from a target position affects the progression of the wavefront and corresponding imaging quality errors. This connection is exploited during alignment in rigid-body degrees of freedom.

Each of the mirrors has a target surface shape which is prescribed in accordance with the specification and which should ideally be present in order to provide the theoretically best possible imaging performance with perfect alignment. In reality, however, there are deviations from the target surface shape caused by numerous sources of errors, wherein these deviations are also referred to as surface figure errors.

In the method shown, the surface shape of each mirror used in the manufacturing process is determined by the manufacturer at the first location LOC1 using a component measurement system CMS as part of a shape measurement. The component measurement system CMS, shown in the diagram, is constructed in the manner of a Fizeau interferometer. As such measurement devices are known per se, a detailed description is omitted here. Examples can be gathered, for example, from WO 2006/077145 A2.

In the example method, the surface shape of each mirror used in the course of production is determined by shape measurement, such as with the very same component measurement system CMS. Features of this approach will be explained further below. In short, the negative influence of an unavoidable absolute error of the component measurement technology used can be eliminated where an issue is the differences of the surface figures, i.e. the difference surface figures between mirrors. More details will be explained below.

The projection lens PO is designed such that some or all mirrors can be exchanged relatively easily, for example for maintenance and repair purposes. For this purpose, each mirror is part of an optical module that can be installed at an assigned installation position with a fixed spatial relationship with the force frame and can also be removed and exchanged without great effort due to its design. In this example, all mirrors are thus integrated into optical modules, which are designed as replacement modules. There are other embodiments in which only a subset of the mirrors is easily exchangeable in this manner.

In the context of the method for producing the projection lens, different types of optical modules are used, which are identified in FIG. 2 by different hatching.

In the example, the first mirror M1 and the third mirror M3 are mirrors that are installed once in their position during the method and, if appropriate, changed in their position during the alignment in the region of the installation position, but are not intended to be exchanged again.

At least one of the optical modules is configured as an exchangeable replacement module and is designed with a mirror selected as the correction mirror. These optical modules or mirrors are marked with the reference sign CM (correction mirror). In the example, the projection lens comprises two such correction mirrors, the second mirror M2 and the fourth mirror M4. Their roles will be described below.

In addition, two tool modules with one tool mirror each (with reference sign TM) are also used in the production of the projection lens PO. Each of the exchangeable optical modules with correction mirror CM is assigned exactly one tool mirror TM.

Tool modules with a tool mirror are characterized in that the tool module has mounting structures which are compatible with respect to the installation position of the associated optical module, which is designed as a replacement module and is equipped with a correction mirror CM, so that it can be installed in principle in the same spatial position at the same installation position. Another criterion is that, according to a shape measurement with a component measurement system, the tool mirror should have the same or substantially the same surface shape as the assigned mirror CM selected as the correction mirror.

A tool module with tool mirror TM can therefore be a design twin of the assigned optical module with correction mirror CM. However, an identity of the surface shape and the reflection coating is neither technically possible nor necessary in its entirety. It is sufficient if the tool mirror has substantially the same optical effect as the assigned correction mirror CM, so that meaningful system measurements are also possible if the assigned tool module with the assigned tool mirror is installed in the correct position instead of an optical module with correction mirror.

It may be the case that a projection lens with an installed tool mirror has an optical performance that lies within the specification, with the result that the tool mirror could in principle remain in the fully assembled projection lens.

However, such a correspondence between the tool mirror and the correction mirror is not necessary insofar as the method is designed in such a way that the tool mirror does not remain in the projection lens, but is replaced by the assigned optical module with the correction mirror before commissioning and commencing productive operation.

In the illustrated example, FIG. 2B shows an intermediate stage of the manufacturing process, in which a tool mirror TM is installed for the second mirror M2 and the fourth mirror. In the finished system (FIG. 2D) corresponding optical modules with correction mirror CM are then installed in the same installation positions of the second and fourth mirrors.

For example, the following procedure can be used for manufacturing. First, all mirrors are measured using a component measurement system CMS to determine the surface shapes of the mirrors (i.e. the surface figure). It should be noted that the surface shape or the surface figure of the tool mirrors TM and that of the assigned correction mirrors CM should be known as precisely as possible. Measuring correction mirrors and tool mirrors with the same component measurement system solves potential problems caused by unavoidable absolute errors in the surface-figure measurement technology or the component measurement system CMS, since in the method only the difference surface figures, i.e. the difference between the surface figure of the installed tool mirror and the surface figure of the replacement mirror to be installed, is to be known as precisely as possible. Typically, the surface shapes of all the mirrors to be installed are measured, such as with the same component measurement system.

At the second location LOC2, for example at the location of the end user, a projection lens PO is then assembled, which in part already corresponds to the projection lens to be produced, but instead of the mirrors provided as correction mirrors CM or their optical modules still contains the respective associated tool mirrors TM and their optical modules. The projection lens with installed tool mirrors (see FIG. 2B) can be regarded as an auxiliary imaging system which does not yet have to have the imaging quality used for productive operation within the specification, but the imaging quality should be sufficiently good to commence operation in auxiliary mode, which is used, for example, for alignment in solid-state degrees of freedom.

The auxiliary imaging system is then mechanically aligned as far as possible under control by the system measurement system SMS until the mirrors obtain their initially best possible spatial position in the installation positions. A final system measurement is then carried out to determine the imaging quality of the best-aligned auxiliary imaging system after installation and rigid-body alignment of the optical modules in the installation positions.

This measured imaging quality is then compared with the target imaging quality desired for the productive operation in order to determine any imaging quality errors. These residual aberrations or these remaining imaging quality errors can usually no longer be significantly reduced by alignment in solid-state degrees of freedom.

This is where the correction mirror CM has a role to play. Based on the system measurement and the comparison with the target imaging quality, it is determined which surface shape the correction mirror CM belonging to a tool mirror would have to have in order to reduce the measured wavefront error as far as possible. In other words, for each of the installed tool mirrors, the difference surface figure or the surface shape difference that would be used to achieve an imaging performance in specification is calculated.

As soon as this information is available, the machining of the mirrors selected as correction mirrors CM can be started in order to transform the surface shape into a modified surface shape by this machining in such a way that it is suitable for reducing the imaging error. During this usually very time-consuming work, the assembled auxiliary imaging system (FIG. 2B) can continue to be operated, for example, to prepare further steps for commissioning or to test the projection lens with regard to other specifications.

After finishing the surface machining of the correction mirrors CM, they are then replaced by the respective associated tool mirrors by a replacement operation (swap operation) by removing the optical modules with tool mirrors from the auxiliary imaging system and installing in their place the replacement modules with the respective machined associated correction mirror.

A further system measurement is then carried out, on the basis of which rigid-body alignment is carried out in order to minimize the optical effects of the mechanical installation tolerances. As a rule, there will already be a significant improvement in imaging quality. Experience has shown that this can be optimized by further (small) alignment steps in rigid-body degrees of freedom, which in turn is carried out under the control of the system measurement system SMS until the best possible imaging quality is achieved.

This procedure presented here as an example can offer considerable economic advantages over conventional concepts in terms of resource utilization and time expenditure, without having to compromise on imaging performance. Among other things, the concept can mean that the manufacturer of the projection lens (here at the first location LOC1) does not have to provide any expensive system measurement technology, for example in the form of a spatially resolving wavefront measurement system, for these purposes. The system measurement is carried out by the end user at the second location LOC2, where system measurement technology is already available in the projection exposure apparatus for later productive operation.

The method can also be described in such a way that the end user is initially supplied with a largely unaligned imaging system, but where the surface shape or surface figure of the individual mirrors including the tool mirrors TM is well known through component measurement. Although the manufacturer does not require a system measurement technology that is already available to the user, the procedure offers the possibility to precisely manufacture one or more correction mirrors CM to reduce residual aberrations remaining after the rigid-body alignment. A mirror swap is used for this system correction. However, this does not lead to significant downtimes on the user's side as the projection lens can already be used as an auxiliary imaging system with installed tool mirrors for many tasks prior to commissioning.

The tool mirrors can be used for other purposes after their use in the manufacture of a projection lens, for example in connection with the manufacture of a nominally structurally identical projection lens. They can be used here as tool mirrors or as permanently installed correction mirrors, provided that the quality of the mirror surface, including the reflection coating, is sufficient. The originally installed tool mirrors TM can thus be re-installed in a newly delivered system for first-wavefront measurement and alignment. Depending on the desire, parts of the tool mirrors or of the optical modules can be remanufactured, repaired or interchanged.

A tool mirror can be used successively for a plurality of manufacturing processes, for example for two, three, four, five, six or more manufacturing processes. If the quality is not sufficient after use, a tool mirror can be remanufactured and reused.

What is claimed is:

1. A method of making an optical imaging system for an EUV microlithography apparatus, the optical imaging system comprising a plurality of optical modules, each module carrying a mirror disposed along an imaging beam path from an object plane of the optical imaging system to an image plane of the optical imaging system, the optical modules being located at assigned installation positions of a force frame, at least one of the optical modules being an exchangeable replacement module comprising a correction mirror, the method comprising:
A) determining a surface shape of the correction mirror using a component measurement system;
B) providing a tool module comprising a tool mirror, wherein:
(i) the tool module comprises compatible mounting structures with respect to the installation position of the replacement module′ and
(ii) the tool mirror comprises, according to a shape measurement made using a component measurement system, the same or substantially the same surface shape as the correction mirror;
C) setting up an auxiliary imaging system by installing optical modules each comprising a mirror located at an assigned installation position of the force frame, the tool module being installed at the installation position of the replacement module;
D) determining an imaging quality of the auxiliary imaging system after installation and rigid-body alignment of the optical modules in the installation positions using a system measurement system;
E) comparing the measured imaging quality with a target imaging quality of the optical imaging system to determine an imaging quality error;
F) determining a change in a surface shape of the correction mirror to reduce the imaging quality error;
G) machining the correction mirror to change the surface shape to a modified surface shape suitable to reduce the imaging error;
H) removing the tool module and installing the replacement module comprising the correction mirror comprising the modified surface shape; and
I) after H), determining the imaging quality of the optical imaging system.

2. The method of claim 1, further comprising:
J) assessing the results of I);
K) when J) indicates an imaging quality that is outside a tolerances, aligning installed optical modules in their rigid-body degrees of freedom; and
L) after K), determining the imaging quality of the optical imaging system.

3. The method of claim 2, further comprising repeating J) through L) until the image quality of the optical imaging system is determined to be within the tolerances.

4. The method of claim 1, wherein A) is performed at a first location, and I) is performed at a second location different from the first location.

5. The method of claim 1, wherein A) is performed at a location of a manufacturer of the optical imaging system, and I) is performed at a location of an end user or at a location of a systems integrator.

6. The method of claim 1, wherein I) comprises using a wavefront measurement system to perform the system measurement.

7. The method of claim 1, wherein I) comprises using a spatially resolving wavefront measurement system for a plurality of field points to perform the system measurement.

8. The method of claim 1, wherein I) is performed in the EUV microlithography apparatus.

9. The method of claim 1, wherein I) is performed in the EUV microlithography apparatus, and a measurement system used to perform I) is integrated in the EUV microlithography apparatus.

10. The method of claim 1, wherein A) and B) are performed with the same component measurement system.

11. The method of claim 1, wherein A) further comprises determining a surface shape of each of the imaging system.

12. The method of claim 1, further comprising operating the auxiliary imaging system with the installed tool module in an auxiliary mode to perform tests and/or to prepare commissioning at the second location.

13. The method of claim 12, wherein, at least in phases, D) and the auxiliary mode are simultaneously performed.

14. The method of claim 1, further comprising:
performing at least one further component measurement on the tool mirror with the same component measurement system as was used in B); and
comparing the results of the multiple shape measurements on the same tool mirror performed with the same component measurement system with a temporal distance to determine drift effects of the component measurement system.

15. The method of claim 1, further comprising:
using the same tool mirror in different imaging systems; and
for each of the different imaging systems, determining the imaging quality of the imaging systems when the tool mirror is installed.

16. The method of claim 1, wherein the method is used to do at least one of the following:
produce an optical imaging system configured as a projection lens of an EUV projection exposure apparatus;
restore an optical imaging system configured as a projection lens of an EUV projection exposure apparatus;
produce an optical imaging system configured as a projection lens of an apparatus configured to inspect an EUV lithography mask;
restore an optical imaging system configured as a projection lens of of an apparatus configured to inspect an EUV lithography mask.

17. The method of claim 1, further comprising:
J) assessing the results of I);
K) when J) indicates an imaging quality that is outside a tolerances, aligning installed optical modules in their rigid-body degrees of freedom; and
L) after K), determining the imaging quality of the optical imaging system,
wherein A) is performed at a first location, and I) is performed at a second location different from the first location.

18. The method of claim 17, wherein I) comprises using a wavefront measurement system to perform the system measurement.

19. The method of claim 18, wherein I) is performed in the EUV microlithography apparatus.

20. The method of claim 19, wherein A) and B) are performed with the same component measurement system.
